(19) United States
(12) Patent Application Publication
(10) Pub. No.: US 2026/0095197 A1
(43) Pub. Date: Apr. 2, 2026

(54) MEMORY DEVICE WITH DYNAMIC COMPRESSION TREES

(71) Applicant: SAMSUNG ELECTRONICS CO., LTD., Suwon-si (KR)

(72) Inventors: Deok Jae OH, Suwon-si (KR); Bin WANG, Xi'an (CN); Liyuan ZHANG, Xi'an (CN); Jinseong KIM, Suwon-si (KR); Jihoon NAM, Suwon-si (KR); Yeongon CHO, Suwon-si (CN)

(73) Assignee: SAMSUNG ELECTRONICS CO., LTD., Suwon-si (KR)

(21) Appl. No.: 19/175,709

(22) Filed: Apr. 10, 2025

(30) Foreign Application Priority Data
Sep. 30, 2024 (KR) 10-2024-0133014

(51) Int. Cl. H03M 7/30

(52) U.S. Cl. CPC H03M 7/6058; H03M 7/3064; H03M 7/3084; H03M 7/6011

(57) ABSTRACT

Disclosed are a compressor for a memory device and an operating method thereof. a method of operating the compressor for the memory device includes: extracting first features from pages corresponding to application programs; clustering the first features into clusters, and generating cluster features respectively corresponding to the clusters; generating trees for compression, the trees respectively corresponding to the cluster features; and storing the trees for performing compression in the memory device.

### CROSS-REFERENCE TO RELATED APPLICATIONS

This application claims the benefit under 35 USC § 119 (a) of Korean Patent Application No. 10-2024-0133014, filed on Sep. 30, 2024, in the Korean Intellectual Property Office, the entire disclosure of which is incorporated herein by reference for all purposes.

### BACKGROUND

### 1. Field

The following description relates to a compressor for a memory device and an operating method thereof.

### 2. Description of Related Art

When a main memory area is insufficient in for current needs of a system, an operating system may move data (e.g., a page in a Linux system that uses virtual memories) of a memory area, which is already allocated to an application program, to a swap area of a non-volatile memory used as an auxiliary memory device to free up a main memory area, thereby resolving a memory shortage phenomenon. Moving data (e.g., pages) to an auxiliary memory device requires data to be transmitted through a system bus that is relatively slow compared to a main memory, and the stored data must be read back to the main memory when needed, which may degrade the performance of an application program. To prevent such performance degradation, a data processing method that compresses and stores data in a main memory without moving the data to an auxiliary memory device may be used.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a device for memory compression includes: one or more processors; and memory storing instructions configured to cause the one or more processors to: extract first features from memory pages corresponding to application programs; generate trees for compression by clustering the first features; obtain second features from a target page to be compressed; based on a similarity of the second features with respect to the generated trees, select a target tree corresponding to the target page from among the trees for compression; and perform compression on the target page using the target tree.

The extracting the first features may include: based on first compression results for the respective pages, calculate occurrence frequency ratios for the respective first compression results; and extract the first features as respective arrays corresponding to the first compression results, based on the occurrence frequency ratios.

The tree generating trees may include: clustering the first features into respective clusters; generating cluster features respectively corresponding to the clusters; and generating the trees as respectively corresponding to the cluster features.

The generating the trees may include generating the cluster features using centroids of the respective clusters or using or average features the respective clusters.

The device may further including: a sampling circuit configured to sample the first features, wherein the tree generation circuit is configured to: by clustering the sampled first features into a plurality of groups, generate cluster features corresponding to the plurality of groups; and generate the trees for compression corresponding to the cluster features.

The instructions may be further configured to cause the one or more processors to: sample the first features, and the generating the trees may further comprise: by clustering the sampled first features into respective clusters, generating cluster features respectively corresponding to the clusters; and generate the trees as respectively corresponding to the cluster features.

The device may further include: a tree cache configured to store the trees for compression, wherein the compression includes, in response to a number of the trees for compression stored in the tree cache exceeding a threshold, evicting, from the tree cache, among the trees for compression, a number of static Huffman trees (SHTs) exceeding the preset threshold, based on storage durations or a usage frequencies of the trees for compression.

The compression may be performed adjacent to a memory and in a compute express link (CXL) controller or a large language model (LLM) accelerator.

The compression may be performed to compress data for a zSwap for a Linux kernel, a database (DB) stored in a user space of a memory, or a large language model (LLM).

In another general aspect, a method of operating a compressor for a memory device includes: extracting first features from pages corresponding to application programs; clustering the first features into clusters, and generating cluster features respectively corresponding to the clusters; generating trees for compression, the trees respectively corresponding to the cluster features; and storing the trees for performing compression in the memory device.

The extracting of the first features may include: based on first compression results of compressing the pages, calculating an occurrence frequency ratios for the first compression results, respectively; and extracting the first features as arrays corresponding to the first compression results, respectively, the extracting based on the occurrence frequency ratios.

The first compression results may include: literals included in the pages; lengths of overlaps of the literals in the pages; and distances between the overlaps of the literals.

The clustering may be performed using K-means clustering based on similarity between the first features.

The cluster features may be generated using centroids of the respective clusters or averages of the respective clusters.

The method may further include: temporarily storing the first features in a storage space of the memory device.

The method may further include: sampling the first features, wherein the generating of the cluster features includes generating the cluster features by clustering the sampled first features into the clusters.

The method may further include: storing associations between third features and the trees, respectively, wherein the third features are the first features or features derived therefrom; determining similarities between a feature of a target page and the third features; selecting whichever tree is, according to the associations, associated with the third feature having the highest similarity to the feature of the target page; and compressing the target page with the selected tree.

The memory device may include a tree cache configured to store the trees for compression, wherein the memory device, in response to a number of the trees stored in the tree cache exceeding a preset threshold, evicts, from the tree cache, a number of trees exceeding the preset threshold, based on storage periods or usage frequencies of the trees, wherein the trees include static Huffman trees (SHTs).

In another general aspect, an method of operating a compressor for a memory device includes: receiving a compression request for a target page to be compressed among pages corresponding to application programs; generating second features of the target page in response to the compression request; based on similarities of the second features with respect to pre-generated trees for compression, selecting a target tree with the highest similarity with respect to the target page from among the pre-generated trees for compression; and performing compression on the target page using the selected target tree.

The generating of the second features may include: outputting a compression result for the target page through a Lempel-Ziv (LZ)-based encoder; and extracting the second features as an array for the compression result for the target page, based on an occurrence frequency ratio for the compression result for the target page.

A non-transitory computer-readable storage medium stores instructions that, when executed by a processor, cause the processor to perform any of the methods.

Other features and aspects will be apparent from the following detailed description, the drawings, and the claims.

### BRIEF DESCRIPTION OF THE DRAWINGS

FIG. 1 illustrates an overview of an example operation of a compressor for a memory device, according to one or more embodiments.

FIG. 2 illustrates an example of a compressor for a memory device, according to one or more embodiments.

FIG. 3A illustrates an example structure of a compressor for a memory device, according to one or more embodiments.

FIG. 3B illustrates an example configuration of a memory device including a compressor and a host central processing unit (CPU), according to one or more embodiments.

FIG. 4A illustrates an example of an operation of a feature extraction circuit, according to one or more embodiments.

FIG. 4B illustrates an example of first compression results for pages, according to one or more embodiments.

FIG. 5 illustrates an example operation of a tree generation circuit, according to one or more embodiments.

FIG. 6 illustrates an example operation of a selection circuit, according to one or more embodiments.

FIG. 7 illustrates an example operation of a compression circuit, according to one or more embodiments.

FIG. 8 illustrates an example of structure and operation of a tree cache, according to one or more embodiments.

FIG. 9 illustrates an example of using a compressor for a memory device, according to one or more embodiments.

FIGS. 10 to 13 illustrate examples of an operating method of a compressor for a memory device, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

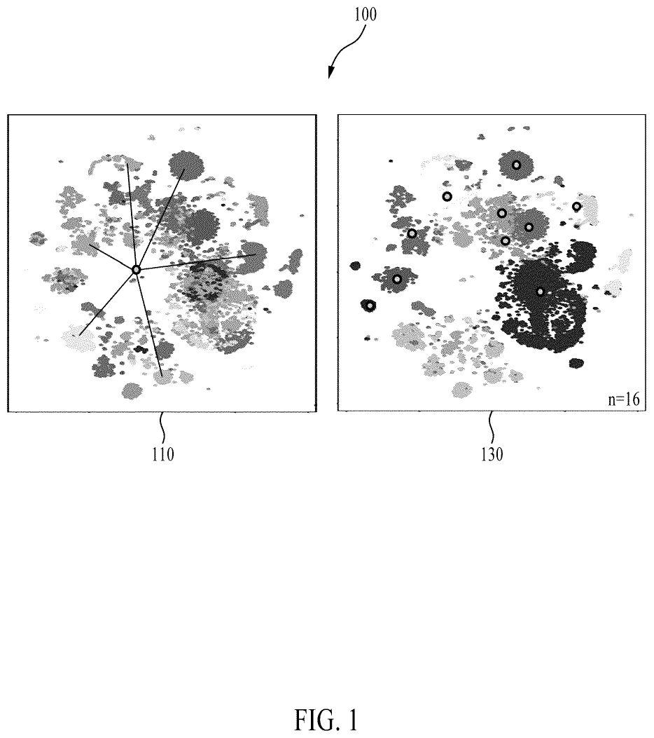

FIG. 1 illustrates an overview of an example operation of a compressor for a memory device, according to one or more embodiments. In FIG. 1, diagram 110 represents a case of clustering a large amount of data of various application programs into a single cluster and diagram 130 represents a case of clustering a large amount of data of various application programs into multiple clusters.

In FIG. 1, each shaded dot (not the circles) represents one memory page, and the shade of each dot represents an application program (different programs are represented by different respective shades). In addition, the distances between each pair of dots represents the similarity between corresponding pieces of data.

The pages are process pieces of memory/storage and each has a same small fixed-size, for example, 4 kilobytes (Kbytes) or 8 Kbytes but is not necessarily limited thereto. The page may be used as a basic unit of memory management. Operation of a process may be performed in page units. The number of possible pages may depend on the page size and the number of expressible bits supported by a processor.

Pieces of data in the memory of a system may have different features depending on the values forming each piece of data. Considering these features, as shown in the diagram 110, when clustering is performed using only one tree (e.g., a static Huffman tree (SHT)) for compression corresponding to a single cluster, a high compression rate may not be guaranteed because features of all pages may not be reflected.

As shown in the diagram 130, among pieces of data, similar pieces of data may be clustered into multiple clusters according to data features of each application program by a clustering technique, and trees for compression that are optimized for clustered groups may be generated.

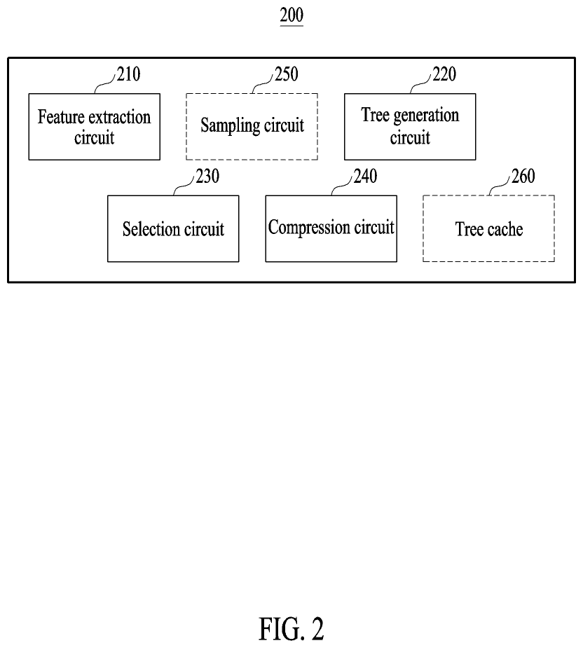

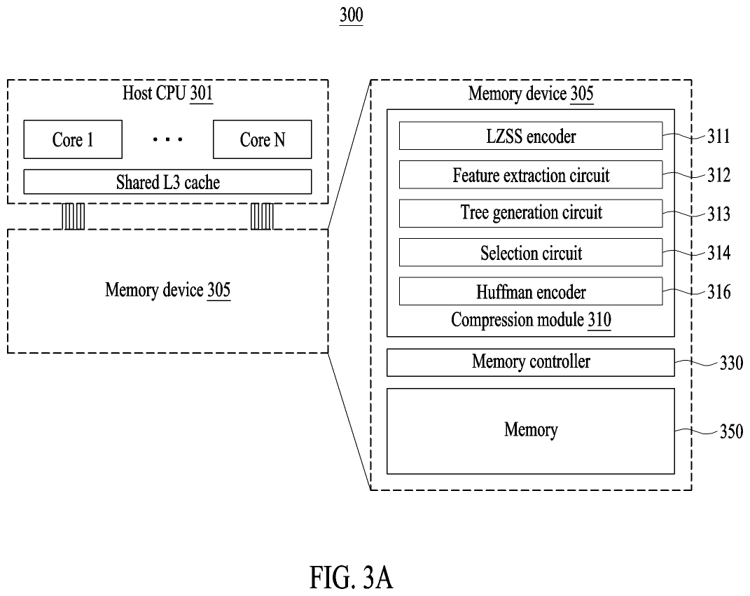

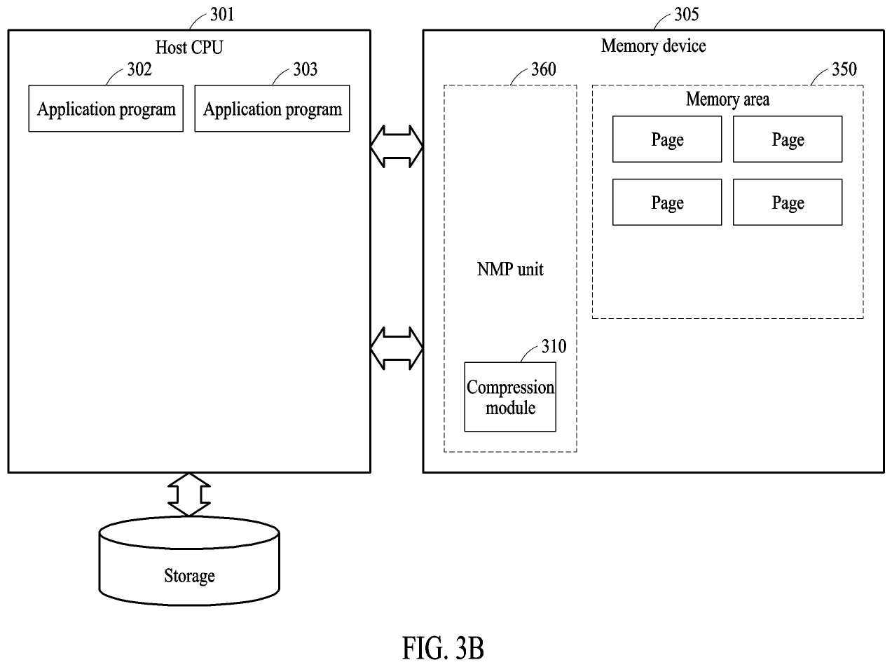

The compression rate may be improved by a hardware device (e.g., a hardware compressor 200 of FIG. 2 or a compression module 310 of FIGS. 3A and 3B) that pre-generates multiple trees for compression according to data features of various application programs and performs compression by selecting, among the pre-generated trees, one tree (a ‘target tree’) that has the feature most similar to new data when compression for the new data is requested.

FIG. 2 illustrates an example of a compressor for a memory device. Referring to FIG. 2, a compressor 200 for a memory device (hereinafter, referred to as a ‘compressor’) may include a feature extraction circuit 210, a tree generation circuit 220, a selection circuit 230, and a compression circuit 240. The compressor 200 may further include a sampling circuit 250 and/or a tree cache 260. Although characterized as circuits, such components may be implemented as similarly performing units of code/instructions.

As described below with reference to FIG. 3A, the compressor 200 may be a deflate compressor that performs lossless compression on data through Lempel-Ziv (LZ) compression and Huffman coding (here, “compression” also refers to “decompression”).

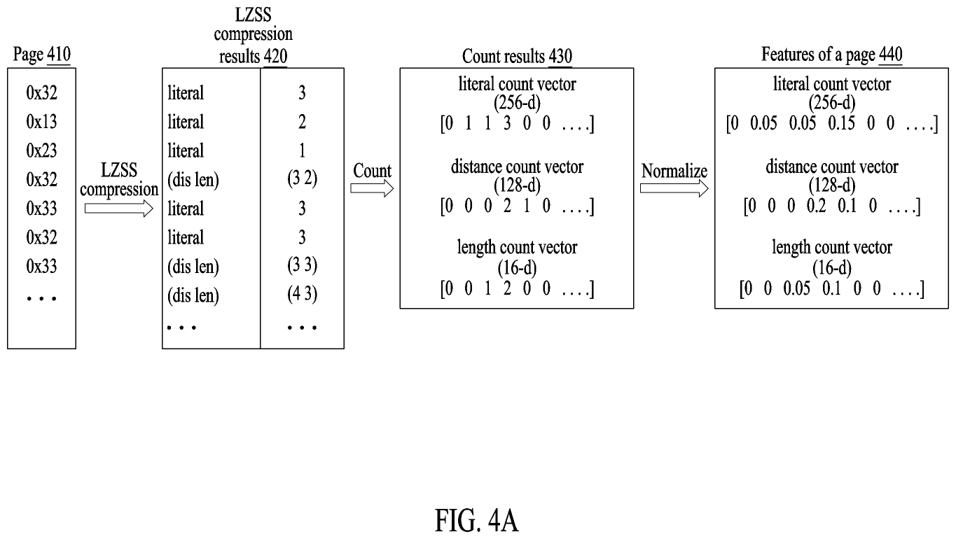

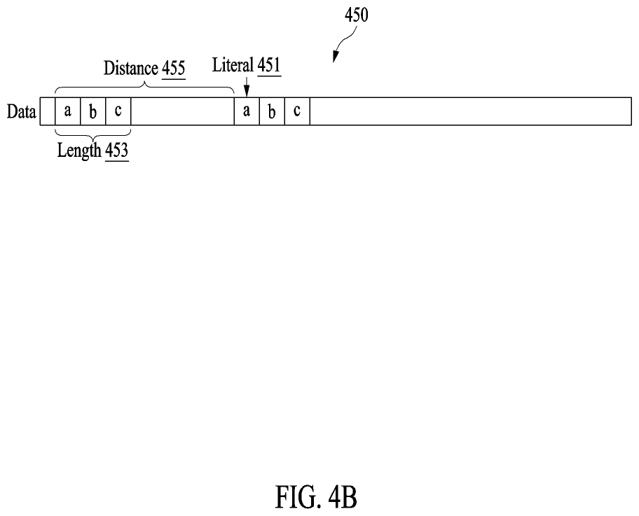

The feature extraction circuit 210 may extract first features from pages of application programs. In response to receiving first compression results for the pages from an LZ-Storer-Szymanski (LZSS) encoder, the feature extraction circuit 210 may calculate occurrence frequency ratios for the first compression results, respectively. For example, the first compression results may be obtained through an LZ-based encoder. As described with reference to FIG. 4B, the first compression results may include literals in the pages, the lengths of overlaps of the literals in the pages, and distances between the overlaps of the literals in the pages. Here, the occurrence frequency ratio of a first compression result may be obtained by the occurrence frequency of each value in the first compression results and/or total occurrence frequency.

The feature extraction circuit 210 may extract the first features (e.g., first features 440 of FIG. 4A) in the form of arrays respectively corresponding to the first compression results, and may do so based on the occurrence frequency ratios. The first features may be, for example, an array of vectors, as a non-limiting example. The operation of the feature extraction circuit 210 is described with reference to FIG. 4A.

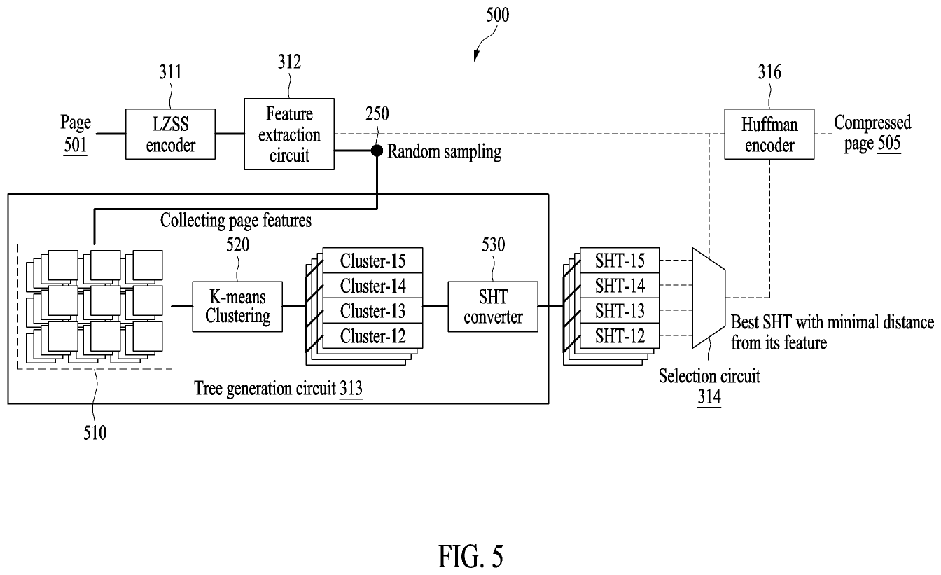

The tree generation circuit 220 may generate trees (to be used for compression) by clustering the first features extracted by the feature extraction circuit 210. The trees for compression may be, for example, SHTs but are not necessarily limited thereto. The tree generation circuit 220 may cluster the first features into groups/clusters. The tree generation circuit 220 may generate cluster features respectively corresponding to the groups/clusters. The tree generation circuit 220 may generate the cluster features using centroids of the groups or averages of the first features in each of the groups, but is not necessarily limited thereto. The tree generation circuit 220 may generate the trees for compression corresponding to the cluster features. The operation of the tree generation circuit 220 is described with reference to FIG. 5. Associations between the cluster features and their respectively corresponding trees may be maintained.

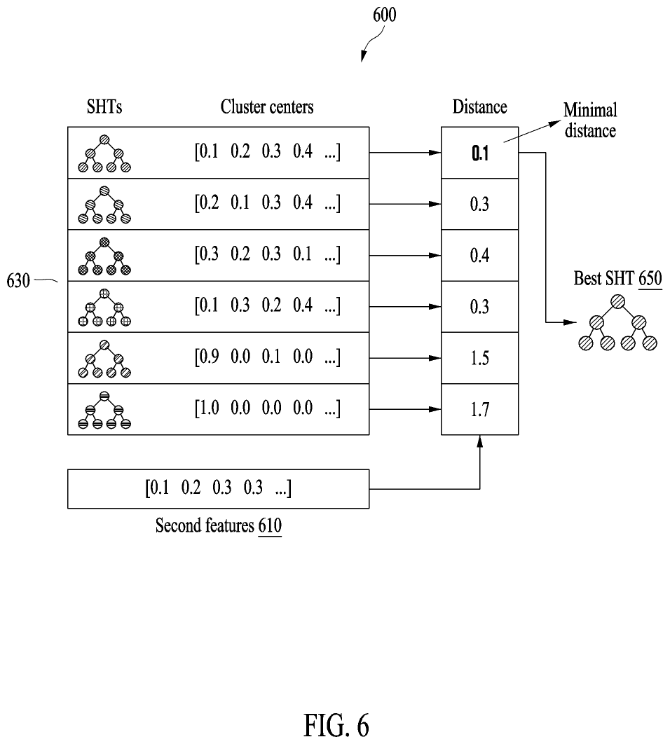

Based on the similarity of second features of a target page (a page to be compressed) with respect to the cluster features, the selection circuit 230 may select a target tree corresponding to the target page from among the trees for compression generated by the tree generation circuit 220. For example, whichever tree is associated (per the stored associations) with the cluster feature that is closest to the second features may be selected as the target tree. The operation of the selection circuit 230 is described with reference to FIG. 6.

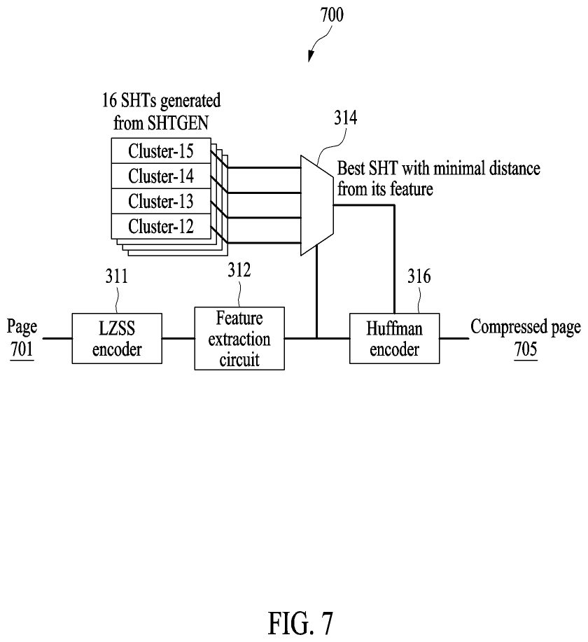

Using the target tree selected by the selection circuit 230, the compression circuit 240 may perform compression on the target page. The compression circuit 240 may correspond to, for example, a circuit that performs Huffman compression through Huffman encoding but is not necessarily limited thereto. The operation of the compression circuit 240 is described in more detail below with reference to FIG. 7.

The sampling circuit 250 may sample the first features extracted by the feature extraction circuit 210 (as opposed to using all first features of the pages thereof). By clustering the first features sampled by the sampling circuit 250 into groups/clusters, the tree generation circuit 220 may generate the cluster features respectively corresponding to the groups/clusters and, from the cluster features, generate the trees respectively corresponding to the cluster features.

The tree cache 260 may store the trees for compression (e.g., the SHTs) generated by the tree generation circuit 220. The tree cache 260 may be a cache memory space for temporarily storing up to N SHTs. The SHTs may be generated by the tree generation circuit 220 and stored in the order in which the SHTs are inserted (input) into the tree cache 260. When new SHTs are generated by the tree generation circuit 220 when a storage space of the tree cache 260 is full, the compressor 200 may evict, from the tree cache 260, among the SHTs stored in the tree cache 260, the oldest SHT stored in the tree cache 260 or an SHT having the lowest usage frequency and may add the new SHTs to the tree cache 260. Here, each of the SHTs stored in the tree cache 260 may further include bits that count their usage frequencies.

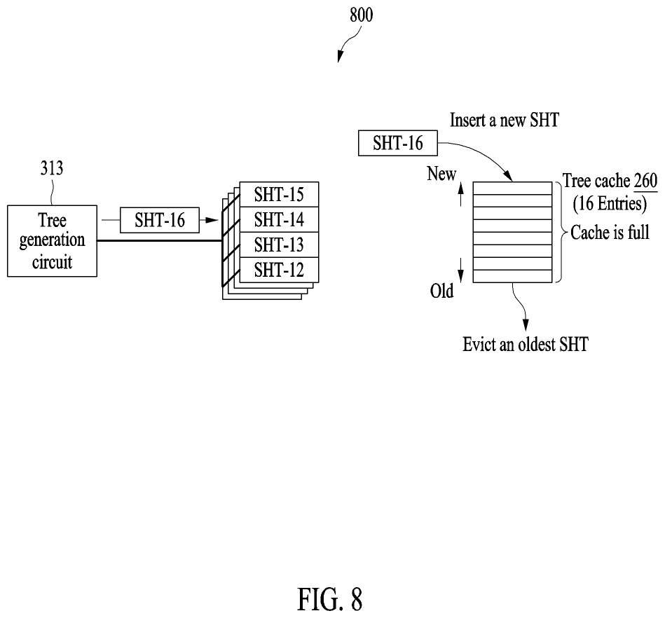

The compressor 200 may determine whether the number of SHTs stored in the tree cache 260 exceeds a preset threshold. When it is determined that the number of SHTs stored in the tree cache 260 exceeds the preset threshold, the compressor 200 may evict, from the tree cache 260, among the SHTs, the number of SHTs exceeding the preset threshold, and which are evicted may be determined based on storage periods or usage frequencies of the SHTs stored in the tree cache 260. The preset threshold may be, for example, 16. The structure and operation of the tree cache 260 are described with reference to FIG. 8.

The compressor 200 may be located adjacent to a memory, such as a near memory processing (NMP) unit (e.g., an NMP unit 360 of FIG. 3B), and perform real-time compression. For example, the compressor 200 may be included in a compute express link (CXL) controller or a large language model (LLM) accelerator, as non-limiting examples.

The compressor 200 may manage a memory area to be allocated to an application program requiring a large amount of memory through the configuration and operation described above. This management technique may be applied in various computer systems such as a mobile device and a server.

The compressor 200 may be executed by a dedicated acceleration unit (a processing near memory (PNM)) near a memory. The compressor 200 may, incidentally by its design, dynamically update SHTs optimized for each workload according to a workload being executed in a system, thereby responding to workload changes. As SHTs that are more relevant to the current pages being compressed populate the tree cache, the more effective the overall compression becomes. That is to say, the compressor 200 may automatically optimize itself for the current makeup of pages being compressed.

The compressor 200 may solve the problem of the sometimes low compression ratio of static Huffman coding by generating SHTs optimized for various workloads by clustering pieces of data (e.g., the first features for the pages) and performing compression by applying SHTs optimized for data (e.g., the target page) that receives a compression request. The compressor 200 may also be referred to as a ‘compression accelerator’ or an ‘accelerator’ in that the compressor 200 accelerates compression.

FIG. 3A illustrates an example structure of a compressor for a memory device, according to one or more embodiments. In FIG. 3A, diagram 300 shows structure of a memory device 305 including a compression module 310 connected to a host central processing unit (CPU) 301.

As described above, the compression module 310 may be a deflate compressor (decompressor) that is included in the memory device 305 and performs lossless compression on data through LZSS compression and Huffman coding.

Due to its high compression ratio, the deflate compressor is preferred in a system in which performance is important. However, static Huffman coding with improved performance may be preferred over dynamic Huffman coding due to the overhead of dynamic Huffman coding during deflate compression (decompression). The dynamic Huffman coding method may not only increase the complexity of hardware implementation but may also make it difficult to expect high performance. The compression module 310 may be a hardware device including a Huffman encoder 316 that uses the static Huffman coding method.

The static Huffman coding method may have high performance, but when one Huffman tree optimized for certain data is used, it may be difficult to guarantee a high compression ratio in a system in which various workloads are executed. That is, static Huffman trees tend to be effective mostly for data with common characteristics, and when the content of data being compressed changes, static Huffman trees should also change. Accordingly, the compression ratio may be improved in various workloads while guaranteeing the compression performance by clustering features of pages corresponding to application programs for each data feature and generating SHTs.

The compression module 310 may include, for example, the compressor 200 described above with reference to FIG. 2 but is not necessarily limited thereto. The compression module 310 may generally perform the same operation as the compressor 200.

The host CPU 301 may include cores (e.g., core 1, . . . , core N) and a shared L3 cache. Unlike L1 and L2 caches embedded in an individual CPU core, an L3 cache is a cache memory that may be accessed by the entire processor and may operate in the form of a shared memory pool. Depending on the location, speed, and size of a memory, a cache memory may be divided into L1, L2, and L3 caches, and an L4 cache may be added occasionally. The L3 cache is slower than the L1 and L2 cache levels but may correspond to a cache memory having the largest capacity of all memory levels.

As an operating system and/or application program(s) are executed, the host CPU 301 may transmit commands and/or data to the memory device 305 and receive data from the memory device 305.

The memory device 305 may include the compression module 310, a memory controller 330, and a memory 350 (or a memory module).

The compression module 310 may generate trees (which are to be used for compression) using clustering and perform compression (e.g., Huffman compression) on new data by selecting the SHT most likely to have the highest compression ratio for the new data (e.g., one whose features are closest to the features of the new data (e.g., a target page) to be compressed).

The compression module 310 may further include an LZSS encoder 311 and the Huffman encoder 316 in addition to a feature extraction circuit 312 (e.g., see the feature extraction circuit 210 of FIG. 2), a tree generation circuit 313 (e.g., see the tree generation circuit 220 of FIG. 2), and a selection circuit 314 (e.g., see the selection circuit 230 of FIG. 2) described above with reference to FIG. 2. The compressor 200 described above may be located between the LZSS encoder 311 and the Huffman encoder 316.

The LZSS encoder 311 may search for data to find repeated literal strings and perform LZSS compression that compresses the repeated literal strings by replacing the repeated literal strings with pointers. Here, each pointer may indicate the location and length of a corresponding literal strings.

The Huffman encoder 316 may encode the data (e.g., an LZSS compression result) generated in the LZSS compression process into code with a variable length according to the occurrence frequency. The Huffman encoder 316 may convert frequently occurring data, that is, data with a high occurrence frequency, into code with short bit length, and rarely occurring data, that is, data with a low occurrence frequency, into code with long bit length.

The compression module 310 may be configured in the memory device 305 or may be configured in the form of another accelerator that is located adjacent to the memory device 305.

The feature extraction circuit 312 may extract features (e.g., first features) of the results output through the LZSS encoder 311; the results being based on LZ encoding.

The tree generation circuit 313 may generate trees (e.g., SHTs) for compression corresponding to data features of the application programs by applying a clustering technique, based on the features extracted by the feature extraction circuit 312.

The selection circuit 314 may select, among the SHTs generated by the tree generation circuit 313, any one SHT (a ‘target tree’) determined to have the highest similarity with respect to second features of a target page in which data is to be compressed.

The memory controller 330 may perform memory management in relation to the operating system and execution of the application programs.

The memory 350 may also be referred to as a ‘memory module’ and may store instructions (or programs) executable by the host CPU 301. For example, the instructions may include instructions for executing operations of the host CPU 301 and/or operations of each component of the host CPU 301.

The memory 350 may be implemented as a volatile memory device and/or a non-volatile memory device. The volatile memory device may be implemented as dynamic random-access memory (DRAM), static RAM (SRAM), thyristor RAM (T-RAM), zero capacitor RAM (Z-RAM), or twin transistor RAM (TTRAM). The non-volatile memory device may be implemented as electrically erasable programmable read-only memory (EEPROM), flash memory, magnetic RAM (MRAM), spin-transfer torque (STT)-MRAM, conductive bridging RAM (CBRAM), ferroelectric RAM (FeRAM), phase change RAM (PRAM), resistive RAM (RRAM), nanotube RRAM, polymer RAM (PoRAM), nano floating gate memory (NFGM), holographic memory, a molecular electronic memory device, or insulator resistance change memory.

FIG. 3B illustrates an example of a configuration of a memory device including a compressor and a host CPU, according to one or more embodiments.

FIG. 3B shows an operation between the host CPU 301 and the memory device 305 including an NMP unit 360 forming the compression module 310.

The host CPU 301 may refer be the main management entity of a computer system. The host CPU 301 may be implemented as a personal computer (PC) or a server. The host CPU 301 may transmit necessary commands to the memory device 305 while executing an operating system and application programs. The host CPU 301 may execute a plurality of application programs 302 and 303. The host CPU 301 may manage data of the memory device 305 for executing the plurality of application programs 302 and 303. Pieces of data of the application programs 302 and 303 may be stored in the memory 350 in a page unit (e.g., a unit of 4 Kbytes or a unit of 8 Kbytes).

The memory device 305 may include the memory 350 and the NMP unit 360 including the compression module 310 described above.

The memory device 305 may operate according to a command of the host CPU 301.

The memory device 305 may provide data to the host CPU 301 when necessary.

The memory 350 may be divided into a general memory area and a compression memory area. The memory 350 may store page(s) of the application programs 302 and 303 (e.g., user space pages, although not so limited). The page(s) may correspond to an operation unit of a process.

The NMP unit 360 may exist spaced apart from the host CPU 301. As shown in FIG. 3B, the NMP unit 360 may be implemented inside the memory device 305 or may be implemented adjacent to the memory device 305. ‘Being implemented adjacent to the memory device 305’ refers to being implemented in a location where data stored in the memory 350 may be accessed without passing through a main data bus between the host CPU 301 and the memory 350. Since the NMP unit 360 may be implemented adjacent to the memory 350, data may be quickly processed without passing through the main data bus between the host CPU 301 and the memory 350.

The NMP unit 360 may process data of the memory 350 by interoperating with the host CPU 301. The NMP unit 360 may control the memory 350 in response to the command of the host CPU 301.

The NMP unit 360 may include a processing unit that processes data. The processing unit may execute computer-readable code (e.g., software) stored in the memory 350 and instructions triggered by a processor. The ‘processing unit’ may be a data-processing device implemented by hardware having a circuit of a physical structure to execute desired operations. For example, the desired operations may include code or instructions in a program. The hardware-implemented data-processing device may include, for example, a microprocessor, a CPU, a processor core, a multi-core processor, a multiprocessor, an application-specific integrated circuit (ASIC), and a field-programmable gate array (FPGA).

The NMP unit 360 may receive a command from the host CPU 301. The command may be, for example, a compression request for a specified target page to be compressed, a compression request for data stored in an in-memory database (IMDB), a compression request for data of an LLM, or a zSwap command for compression in a Linux kernel, as non-limiting examples.

The NMP unit 360 may perform compression or decompression on data in response to the command. The NMP unit 360 may manage entries of the compressed data.

The NMP unit 360 may generate an entry tree configured with a tree structure or a hash structure, based on the compressed data. The NMP unit 360 may manage the entries based on the entry tree.

The NMP unit 360 may include a buffer (not shown). The buffer may include an input buffer and an output buffer. The NMP unit 360 may perform reading by receiving information about data stored in the input buffer from the host CPU 301. The NMP unit 360 may perform data writing on the output buffer and output information about the written data to a predetermined memory area. For example, the predetermined memory area may include, but is not necessarily limited thereto, a main memory area of the host CPU 301, a second memory area such as a CXL, or a memory area of a near data processor (NDP).

The NMP unit 360 may perform decompression on the compressed data. The NMP unit 360 may output the decompressed data to the host CPU 301. The NMP unit 360 may evict an entry corresponding to the decompressed data from the entry tree. The NMP unit 360 may store the compressed data or data in a buffer based on the entry.

The NMP unit 360 may store the compressed data or the decompressed data in a near-memory area. The near-memory area may be a storage space that the NMP unit 360 can access without passing through the main data bus between the host CPU 301 and the memory 350.

The NMP unit 360 including the compression module 310 may efficiently process data by performing compression, decompression, and memory area management functions in a state implemented adjacent to or inside the memory device 305.

FIG. 4A illustrates an example of operation of a feature extraction circuit, according to one or more embodiments, and FIG. 4B illustrates an example of first compression results for pages, according to one or more embodiments.

Referring to FIGS. 4A and 4B, pages 410 corresponding to application programs may be stored in a memory area of a memory device. The pages 410 may store values in the form of, for example, 0x32, 0x13, 0x23, 0x32, 0x33, etc.

A compressor (e.g., the compressor 200 of FIG. 2) or a compression module (e.g., the compression module 310 of FIG. 3) may use an LZSS encoder (e.g., the LZSS encoder 311 of FIG. 3) to perform LZ-based compression on the values stored in the pages 410, thus obtaining a high compression ratio. The compressor may then sequentially perform static Huffman compression by a Huffman encoder (e.g., the Huffman encoder 316 of FIG. 3), using a SHT, for example.

LZSS compression results 420 may be output when the LZSS encoder 311 performs LZSS compression on the pages 410. The compressor may perform primary compression by applying an LZ algorithm to the pages 410 and may output the LZSS compression results 420 obtained by calculating the literals 451 forming the pages 410, lengths 453 of overlaps of the literals matching each other in the pages 410, and a distance 455 between literal overlaps in the pages 410.

As shown in diagram 450, the LZSS compression results 420 may include the each literal 451 (e.g., a, b, and c) (e.g., 8 bits) in the pages 410, the lengths 453 (e.g., 4 bits) of the literal overlaps (e.g., a, b, and c) in the pages 410, and the distances 455 (e.g., 7 bits) between the literal overlaps in the pages 410.

In the LZSS compression results 420, the word “literal” represents each different literal in the pages 410. In addition, in the LZSS compression results 420, the phrase “(dis len)” represents the length 453 (“len”) of the literal overlaps in the pages 410 and the distances 455 (“dis”) between the literal overlaps. For example, “(dis len)” being “(3 2)” indicates that the distance between literals overlapping each other in a corresponding page is ‘3’ and the length of the literals overlaps in the corresponding page is ‘2.’

The compressor may calculate count results 430 which is a set of counts of the occurrence frequency of each literal 451, the lengths 453 of the literal overlaps, and the distances 455 between the literal overlaps in the pages 410.

The compressor may count the number of occurrences for the each literal 451. For example, the compressor may count the occurrences for each of 256 characters included in the 7-bit American standard code for information interchange (ASCII) code including literals, numbers, special letters, symbols, etc., and generate a literal count vector. In this case, the literal count vector may be configured with 256 dimensions. For example, the in the example literal count vector [0, 1, 1, 3, 0, . . . ], among the 256 characters included in the 7-bit ASCII code, first and fifth characters do not occur, second and third characters occur once each, and a fourth character occurs three times.

In addition, the compressor may count the distances 455 between the literal strings overlapping each other in the pages 410 and generate a distance count vector. The distance count vector may be configured with 128 dimensions. For example, the fact that the distance count vector is [0, 0, 0, 2, 1, 0, . . . ] indicates that, among the 256 characters, a fourth character overlaps twice and a fifth character overlaps once.

In addition, the compressor may count the lengths 453 of the literal overlaps in the pages 410 and generate a length count vector. The length count vector may be configured with 16 dimensions. For example, the fact that the length count vector is [0, 0, 1, 2, 0, 0, . . . ] indicates that there is one literal having a length of 3 bits overlapping each other (a 3-bit overlap) in the pages 410 and two literal strings having a length of 4 bits overlapping each other (a 4-bit overlap).

The compressor may generate first features 440 in the form of an array expressed as an occurrence frequency ratio corresponding to the LZSS compression results 420 by normalizing the count results 430.

The first features 440 may correspond to each of the compressed result values, that is, the each literal 451 in the pages 410, the lengths 453 of the literals overlapping each other in the pages 410, and the distances between the literal strings overlapping each other in the pages 410, and may be configured with, for example, 256 dimensions, 128 dimensions, and 16 dimensions.

The compressor may extract/generate, according to the count results 430, the first features 440 in the form of an array, based on the occurrence frequency ratio of each literal 451, the lengths 453 of the literal overlaps, and the distances 455 between the literal strings overlapping each other.

The compressor may compress data by using the Huffman encoder 316, which assigns the least number of bits to symbols representing the most frequently occurring data according to the frequencies/counts of the literals 451, the lengths 453 of the literal overlaps, and the distances 455 between the literal overlaps.

To reduce operation overhead of the dynamic Huffman method, it may be possible to improve the overhead and compression performance by pre-generating SHTs corresponding to features of pages corresponding to application programs and selecting one optimized SHT corresponding to a target page.

FIG. 5 illustrates an example of an operation of a tree generation circuit. FIG. 5 shows a diagram 500 representing a process in which a compressor (e.g., the compressor 200 of FIG. 2 and/or the compression module 310 of FIG. 3) generates trees for compression (e.g., SHTs) and compresses a target page 501 with an optimal tree.

When a compression request for a page to be compressed (the ‘target page’ 501) is received, the compressor may perform primary LZ compression on the target page through the LZSS encoder 311 and output the compressed results. The compressed results may include, according to the LZ compression, statistics on literals in the target page 501, the lengths of literal overlaps in the target page 501, and distances between literal overlaps in the target page 501.

The feature extraction circuit 312 that receives the compressed results from the LZSS encoder 311 may extract (generate), as first features in the form of an array, the results obtained by calculating an occurrence frequency ratio for each value of the compressed results (e.g., LZ compression results) as an occurrence frequency of each compressed result value and/or the total occurrence frequency of the compressed result values. Here, the first features may correspond to each of the compressed result values, that is, the literals in the target page 501, the length of the literal overlaps in the target page 501, and the distance value between the literal strings overlapping each other in the target page 501 and may be configured with, for example, 256 dimensions, 128 dimensions, and 16 dimensions.

The first features extracted by the feature extraction circuit 312 may be temporarily stored in a storage space 510 of the tree generation circuit 313. The storage space 510 may be implemented in the form of, for example, a cache or a buffer but is not limited thereto. The compressor may collect the first features corresponding to various pages by repeatedly performing the process of extracting and storing the first features on many pages.

The compressor may randomly sample some of the first features output from the feature extraction circuit 312 by the sampling circuit 250 and store some of the first features in the storage space 510 to reduce the load of a memory device.

When a certain number of first features are filled in the storage space 510, the tree generation circuit 313 may generate N (e.g., N=16) cluster groups (e.g., Cluster-0, Cluster-1, . . . , Cluster-12, Cluster-13, Cluster-14, and Cluster-15) by grouping similar features of the first features into one group through a clustering operation (e.g., K-means clustering 520). The K-means clustering 520 is a method of supervised learning and may operate in a way that groups similar items (features) into K clusters and minimizes the distance difference between each cluster and data points. The tree generation circuit 313 may randomly select K cluster centroids according to the K-means clustering 520 and then allocate/assign each data point (first feature) to the nearest centroid point. The tree generation circuit 313 may update the centroid of each cluster to an average of the data points in the corresponding cluster and repeat the data allocation and centroid-update process until the allocation of the data points (first features) no longer changes.

The tree generation circuit 313 may generate N cluster feature(s), which are the centers of the cluster groups. The clustering may be based on distances between first features (feature matrices). When the generation of the N cluster feature(s) is completed, the tree generation circuit 313 may convert the N cluster feature(s) into N respective SHTs through an SHT converter 530 and store the N SHTs in a certain storage space. To allow selection of the SHTs, as shown in FIG. 6, each pre-generated SHT may be stored in association with the cluster centroid from which it was derived, thus allowing SHTs to be selected based on similarity (closeness) between a to-be-compressed page's extracted second features and a cluster centroid (a synthetic set of features). The certain storage space may be implemented, for example, in the form of a cache or a buffer in the memory device or may be implemented in some spaces (e.g., a compressed memory area) of a memory.

The operation of the tree generation circuit 313 described above may be performed in parallel or sequentially with respect to the compression operation.

FIG. 6 illustrates an example of an operation of a selection circuit, according to one or more embodiments. In FIG. 6, diagram 600 shows a process in which a selection circuit (e.g., the selection circuit 314 of FIG. 3A and FIG. 5) selects an SHT 650 whose associated cluster centroid is most similar to second features 610 of a target page to be compressed.

The selection circuit 314 may select, among trees for compression (e.g., SHTs 630) that are pre-generated, the SHT 650 having the associated centroid that is most similar feature to the second features 610 of the target page to be compressed. The second features 610 may be, for example, vectors in the form of an array but are not necessarily limited thereto.

The selection circuit 314 may calculate distances between features (cluster centroids) of the respectively associated SHTs 630 and the second features 610 and select, as the SHT 650 (a ‘target tree’), whichever SHT's features/centroid has smallest distance (e.g., 0.1) to the second features 610.

Here, the distance may correspond to the distance between two features (or feature vectors). The distance value may be obtained, for example, through code/instructions analogous to Equation 1 or Equation 2 below; a smaller distance indicating a higher similarity between features.

$$L 1 distance = {\sum }_{i = 1}^{n} \vert {x}_{i} - {y}_{i} \vert \qquad Equation 1$$

Here, xᵢ denotes a feature (a feature vector) of any of the SHTs 630 that are pre-generated, and yᵢ denotes the second features 610 (or feature vectors) of the target page to be compressed.

Equation 1 may also be referred to as an ‘L1 distance’ or ‘L1 norm’ and represents the sum of the absolute values of the differences between two vector values.

$$L 2 distance = {\sum }_{i = 1}^{n} \sqrt{{( {x}_{i} - {y}_{i} )}^{2}} \qquad Equation 2$$

Equation 2 may also be referred to as an ‘L2 distance’ or ‘L2 norm’ and represents the Euclidean distance between two vectors.

In either Equation 1 or Equation 2, the L1 or L2 distance to the target feature vector/matrix may be computed for the feature/centroid of each of the SHTs 630.

FIG. 7 illustrates an example operation of a compression circuit, according to one or more embodiments. In FIG. 7, diagram 700 shows a process in which a compression circuit (e.g., the compression circuit 240 of FIG. 2 and/or the Huffman encoder 316 of FIG. 3) performs compression on a new page 701 to be compressed using trees for compression (e.g., the 16 SHTs 630) generated by a tree generation circuit (e.g., the tree generation circuit 220 of FIG. 2 and/or the tree generation circuit 313 of FIG. 3).

When a compression request for the new page 701 is received, the compressor (e.g., the compressor 200 of FIG. 2 and/or the compression module 310 of FIG. 3) may perform LZ compression on the new page 701 through the LZSS encoder 311 and generate second features for the LZ compression result (e.g., literals in the new page 701, the length of literal overlaps in the new page 701, and distances between literal overlaps in the new page 701, and normalized if needed) of the new page 701 through the feature extraction circuit 312.

The compressor may transmit the second features to the selection circuit 314. The selection circuit 314 may select, as a target tree, among the 16 SHTs 630 that are pre-generated, one SHT having the centroid features that are most similar to the second features. Here, the selection circuit 314 may determine the similarity between features by calculating the distance between the second features and the features/centroids of the 16 SHTs 630 that are pre-generated.

The compressor may transmit the target tree selected by the selection circuit 314 to the Huffman encoder 316, and the Huffman encoder 316 may generate a compressed page 705 corresponding to the new page 701 using the target tree.

FIG. 8 illustrates an example of structure and operation of a tree cache, according to one or more embodiments. In FIG. 8, diagram 800 shows a method of maintaining a certain number of trees for compression in a memory device using the tree cache 260.

Using the tree cache 260 that stores the trees for compression (e.g., SHTs), the number of SHTs generated through a tree generation circuit (e.g., the tree generation circuit 313 of FIG. 3A) may be maintained constant. The tree cache 260 may be included in the compressor or the memory device.

The tree cache 260 may be implemented in a cache memory space and may temporarily store up to N (e.g., N=16) SHTs. The tree cache 260 may have a first-in-first-out (FIFO) structure in which the SHTs are stored in the order into which the SHTs are inserted. When a new SHT (e.g., SHT-16) is generated in a case in which the cache memory space is full, the tree cache 260 may maintain the number of SHTs stored in the tree cache 260 constant by evicting the oldest SHT stored in the tree cache 260 and adding the new SHT to the tree cache 260. Thus, the cached SHTs are more likely to be suitable to the pages currently being compressed or about to be compressed.

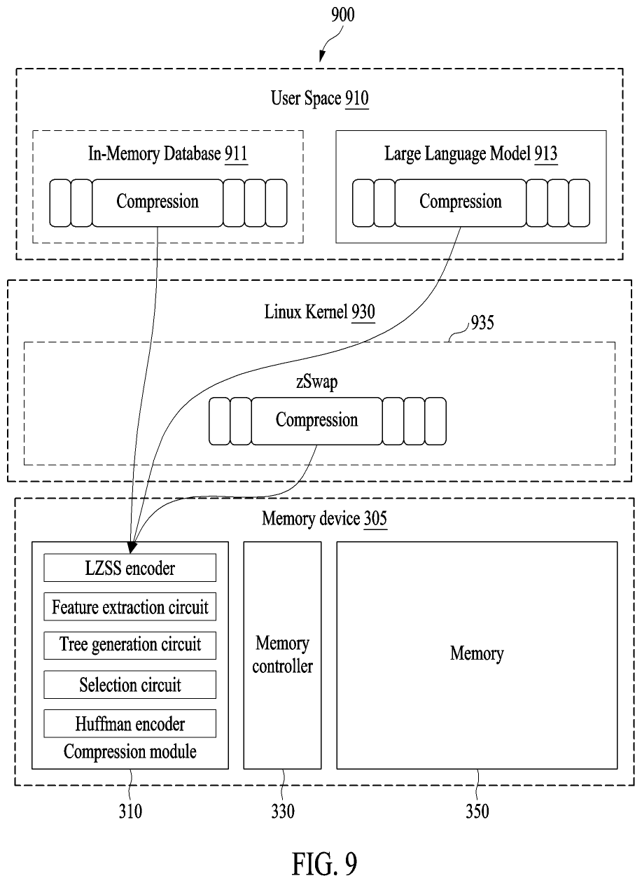

FIG. 9 illustrates an example of using a compressor for a memory device, according to one or more embodiments. In FIG. 9, diagram 900 shows various application examples in which a compressor (e.g., the compressor 200 of FIG. 2 and/or the compression module 310 of FIG. 3) is used.

The compressor may be used in an IMDB 911 of a user space 910 (e.g., for compressing database pages), an LLM 913, and/or a zSwap 935 of a Linux kernel 930.

The IMDB 911 may correspond to a DB management system that stores and processes data in a main memory (e.g., the memory 350) rather than a disk. The IMDB 911 may store a large amount of data in a memory space to provide a service quickly and may improve data access speed by quickly returning the data in response to a request of a client, thereby enabling high-performance data processing.

The IMDB 911 may guarantee high performance compared to a database that stores data in a storage connected to a host CPU, but it may be difficult to configure the storage space used for the DM to be large due to limitations in memory price and memory capacity. An additional memory space may be secured by compressing pieces of data of the DM stored in a memory by the compressor.

Similarly, in the LLM 913, data compression may be performed to increase efficiency and save the storage space. It may be possible to save the storage space and improve data processing speed by compressing the pieces of data of the LLM 913 by the compressor.

In addition, the compressor may also be used in the zSwap 935, which is one of the memory compression functions of the Linux kernel 930.

The zSwap 935 is a software technology that secures the memory space by compressing some pieces of data when a system memory space is insufficient. The zSwap 935 may improve the system performance and reduce a disk input/output (I/O) by compressing data in a swap area and increasing the memory usage efficiency. The operation process of the zSwap 935 may include a generation and management part of a red-black tree (RB tree) for managing information of the compressed data and a memory management part for managing data compression and a memory space of the compressed data. Here, the RB tree is a type of self-balancing binary search tree and may be implemented with an algorithm that automatically balances the tree through a certain rule while maintaining the structure of the binary search tree. The process of compressing data is a complex operation that usually requires significant computing resources and memory access, which may cause system performance degradation.

More memory spaces may be efficiently secured with a high compression rate by processing a data compression operation by an accelerator (e.g., the compressor) near the memory and improving the performance of the zSwap 935. In addition, it may be possible to ensure the compression performance in various application fields together with the compression function by improving data compression performance by the compressor and efficiently securing the memory space with a high compression rate.

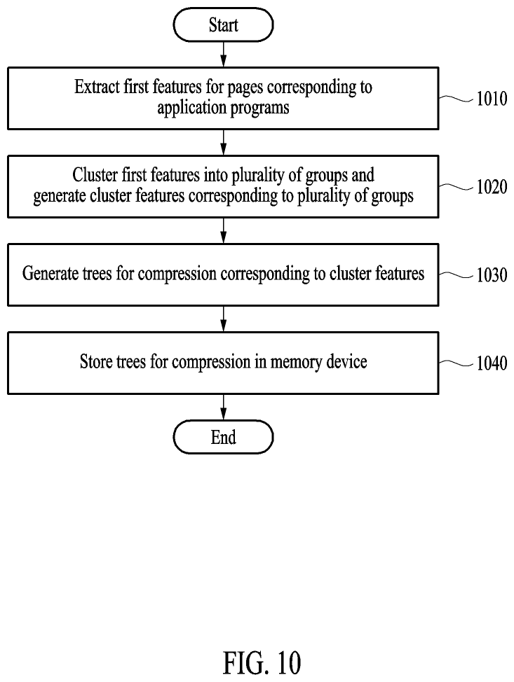

FIG. 10 illustrates an example of an operating method of a compressor for a memory device, according to one or more embodiments.

Referring to FIG. 10, a compressor (e.g., the compressor 200 of FIG. 2 and/or the compression module 310 of FIG. 3) may store trees for compression in the memory device through operations 1010 to 1040.

In operation 1010, the compressor may extract first features for pages corresponding to application programs, for example. In response to receiving first compression results for the pages, the compressor may calculate an occurrence frequency ratio for each value of the first compression results. The first compression results may be obtained through an LZ-based encoder. The first compression results may include literals in the pages, the lengths of literal overlaps in the pages, and/or distances between literal overlaps in the pages but are not necessarily limited thereto. The compressor may extract the first features in the form of arrays or vectors corresponding to the first compression results, and the extraction may be based on their occurrence frequency ratios. The compressor may temporarily store the first features in a storage space of the memory device.

In operation 1020, by clustering the first features extracted from operation 1010 into groups/clusters, the compressor may generate cluster features respectively corresponding to the groups/clusters. The compressor may generate the cluster features corresponding to the groups/clusters by K-means clustering, based on similarity between the first features. The compressor may generate the cluster features using a centroid of each of the groups/clusters or average of the features in the respective groups/clusters.

In operation 1030, the compressor may generate the trees for compression (e.g., SHTs) corresponding to the cluster features generated in operation 1020.

In operation 1040, the compressor may store the trees for compression generated in operation 1030 in the memory device.

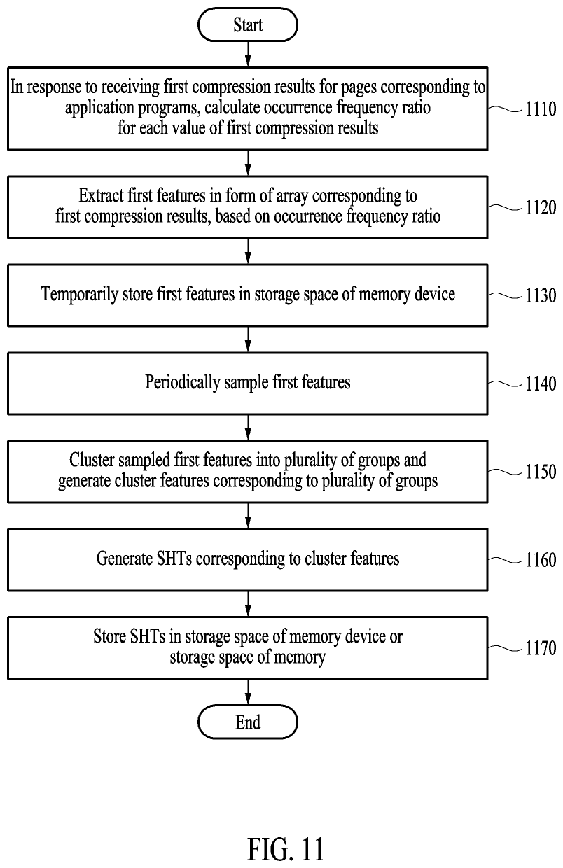

FIG. 11 illustrates an example of an operating method of a compressor for a memory device, according to one or more embodiments. Referring to FIG. 11, a compressor (e.g., the compressor 200 of FIG. 2 and/or the compression module 310 of FIG. 3) may store trees for compression through operations 1110 to 1170.

In operation 1110, in response to receiving first compression results for pages corresponding to application programs, the compressor may calculate an occurrence frequency ratio for each value of the first compression results. Here, the first compression results may be obtained through an LZ-based encoder.

In operation 1120, the compressor may extract first features in the form of arrays respectively corresponding to the first compression results, based on the occurrence frequency ratios calculated in operation 1110.

In operation 1130, the compressor may temporarily store the first features extracted from operation 1120 in a storage space of the memory device.

In operation 1140, the compressor may periodically sample the first features that are temporarily stored in operation 1130.

In operation 1150, the compressor may cluster the first features sampled in operation 1140 into groups and generate cluster features respectively corresponding to the groups.

In operation 1160, the compressor may generate SHTs corresponding to the cluster features generated in operation 1150.

In operation 1170, the compressor may store the SHTs generated in operation 1160 in the storage space of the memory device or a storage space of a memory.

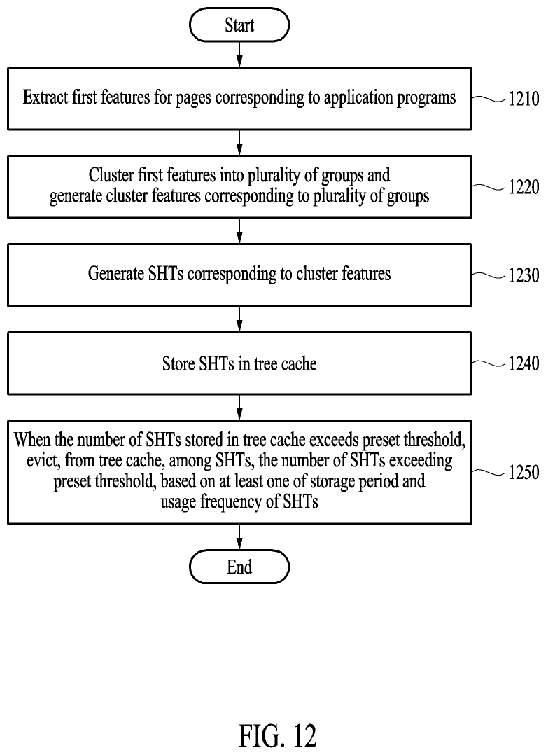

FIG. 12 illustrates an example of an operating method of a compressor for a memory device, according to one or more embodiments. Referring to FIG. 12, a compressor (e.g., the compressor 200 of FIG. 2 and/or the compression module 310 of FIG. 3) may evict, from a tree cache, the number of SHTs exceeding a threshold through operations 1210 to 1250.

In operation 1210, the compressor may extract first features for pages corresponding to application programs. In response to receiving first compression results for the pages, the compressor may calculate an occurrence frequency ratio for each value of the first compression results and may extract the first features in the form of an array corresponding to the first compression results, based on the occurrence frequency ratio.

In operation 1220, the compressor may cluster the first features extracted from operation 1210 into a plurality of groups and generate cluster features respectively corresponding to the groups.

In operation 1230, the compressor may generate trees for compression (e.g., SHTs) corresponding to the cluster features generated in operation 1220.

In operation 1240, the compressor may store the SHTs generated in operation 1230 in the tree cache.

In operation 1250, when the number of SHTs stored in the tree cache in operation 1240 exceeds a preset threshold, the compressor may evict, from the tree cache, among the cached SHTs, the number of SHTs exceeding the preset threshold, and the evicted SHTs may be selected based on a storage period and/or a usage frequency of the SHTs (e.g., oldest or lowest frequency of use are evicted first).

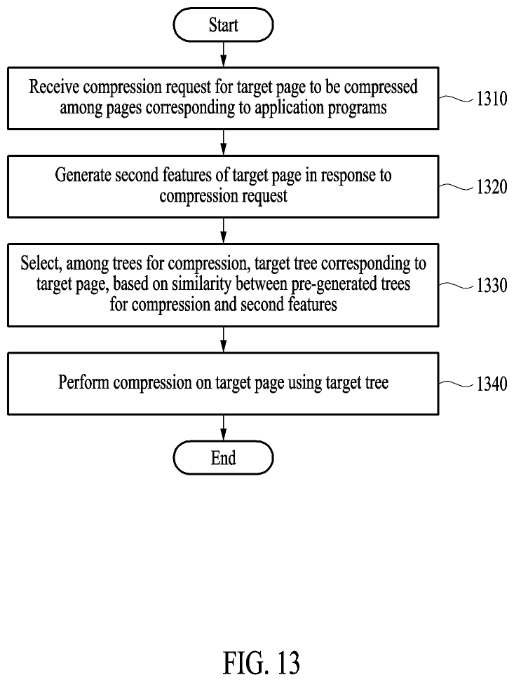

FIG. 13 illustrates an example of an operating method of a compressor for a memory device, according to one or more embodiments. Referring to FIG. 13, a compressor (e.g., the compressor 200 of FIG. 2 and/or the compression module 310 of FIG. 3) may perform compression on a target page through operations 1310 to 1340.

In operation 1310, the compressor may receive a compression request for the target page to be compressed among pages corresponding to application programs.

In operation 1320, the compressor may generate second features, which are features of the target page, and may do so in response to the compression request received from operation 1310. The compressor may output compression results for the target page through an LZ-based encoder. The compression results for the target page may include literals in the target page, the lengths of overlaps of the literals, and distances between the overlaps of the literals in the target page. The compressor may extract the second features in the form of an array for the compression results for the target page, based on an occurrence frequency ratio for the compression results for the target page (i.e., the top-N most frequent features are extracted). Here, the occurrence frequency ratio for the compression results for the target page may be obtained by an occurrence frequency of each value (e.g., the literals, the lengths of the literal overlaps, the distances between the literal overlaps) of the compression results for the target page and/or the total occurrence frequency.

In operation 1330, the compressor may select, among the trees for compression, the target tree corresponding to the target page, based on the similarity between the features/centroids of the pre-generated trees for compression (e.g., the SHTs) and the second features generated in operation 1320. Here, the pre-generated trees and their features may be generated through the process of FIG. 10 and/or FIG. 11 but are not necessarily limited thereto.

In operation 1340, the compressor may perform compression (e.g., compression by Huffman encoding) on the target page using the target tree selected in operation 1330. The compressor may perform Huffman compression on the target page in real time using the target tree selected from among the pre-generated trees for compression.

The examples described herein may be implemented using a hardware component, a software component, and/or a combination thereof. A processing device may be implemented using one or more general-purpose or special-purpose computers, such as, for example, a processor, a controller and an arithmetic logic unit (ALU), a DSP, a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and/or multiple types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as desired. Software and data may be stored permanently or temporarily in any type of machine, component, physical or virtual equipment, computer storage medium, or device capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described examples may be recorded in non-transitory computer-readable media including program instructions to implement various operations of the above-described examples. The media may also include, alone or in combination with the program instructions, data files, data structures, and the like. The program instructions recorded on the media may be those specially designed and constructed for the purposes of examples, or they may be of the kind well-known and available to those having skill in the computer software arts. Examples of non-transitory computer-readable media include magnetic media such as hard disks, floppy disks, and magnetic tape; optical media such as CD-ROM discs and/or DVDs; magneto-optical media such as optical discs; and hardware devices that are specially configured to store and perform program instructions, such as read-only memory (ROM), random access memory (RAM), flash memory, and the like (but not signals per se). Examples of program instructions include both machine code, such as produced by a compiler, and files containing higher-level code that may be executed by the computer using an interpreter.

The computing apparatuses, the electronic devices, the processors, the memories, the information output system and hardware, the storage devices, and other apparatuses, devices, units, modules, and components described herein with respect to FIGS. 1-13 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-13 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROM, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A device for memory compression, the device comprising:
one or more processors; and
memory storing instructions configured to cause the one or more processors to:
extract first features from memory pages corresponding to application programs;
generate trees for compression by clustering the first features;
obtain second features from a target page to be compressed;
based on a similarity of the second features with respect to the generated trees, select a target tree corresponding to the target page from among the trees for compression; and
perform compression on the target page using the target tree.

2. The device of claim 1, wherein the extracting the first features comprises:
based on first compression results for the respective pages, calculate occurrence frequency ratios for the respective first compression results; and
extract the first features as respective arrays corresponding to the first compression results, based on the occurrence frequency ratios.

3. The device of claim 1, wherein the tree generating trees comprises:
clustering the first features into respective clusters;
generating cluster features respectively corresponding to the clusters; and
generating the trees as respectively corresponding to the cluster features.

4. The device of claim 3, wherein the generating the trees generates the cluster features using centroids of the respective clusters or using average features of the respective clusters.

5. The device of claim 1, wherein the instructions are further configured to cause the one or more processors to:
sample the first features,
and wherein the generating the trees further comprises:
by clustering the sampled first features into respective clusters, generating cluster features respectively corresponding to the clusters; and
generate the trees as respectively corresponding to the cluster features.

6. The device of claim 1, further comprising:
a tree cache configured to store the trees for compression,
wherein the compression includes, in response to a number of the trees for compression stored in the tree cache exceeding a threshold, evicting, from the tree cache, among the trees for compression, a number of static Huffman trees (SHTs) exceeding the preset threshold, based on storage durations or a usage frequencies of the trees for compression.

7. The device of claim 1, wherein the compression is performed adjacent to a memory and in a compute express link (CXL) controller or a large language model (LLM) accelerator.

8. The device of claim 1, wherein the compression is performed to compress data for a zSwap for a Linux kernel, a database (DB) stored in a user space of a memory, or a large language model (LLM).

9. A method of operating a compressor for a memory device, the operating method comprising:
extracting first features from pages corresponding to application programs;
clustering the first features into clusters, and generating cluster features respectively corresponding to the clusters;
generating trees for compression, the trees respectively corresponding to the cluster features; and
storing the trees for performing compression in the memory device.

10. The method of claim 9, wherein the extracting of the first features comprises:
based on first compression results of compressing the pages, calculating an occurrence frequency ratios for the first compression results, respectively; and
extracting the first features as arrays corresponding to the first compression results, respectively, the extracting based on the occurrence frequency ratios.

11. The method of claim 10, wherein the first compression results comprise:
literals comprised in the pages;
lengths of overlaps of the literals in the pages; and
distances between the overlaps of the literals.

12. The method of claim 9, wherein the clustering is performed using K-means clustering based on similarity between the first features.

13. The method of claim 9, wherein the cluster features are generated using centroids of the respective clusters or averages of the respective clusters.

14. The method of claim 9, further comprising:
temporarily storing the first features in a storage space of the memory device.

15. The method of claim 9, further comprising:
sampling the first features,
wherein the generating of the cluster features comprises generating the cluster features by clustering the sampled first features into the clusters.

16. The method of claim 9, further comprising:
storing associations between third features and the trees, respectively, wherein the third features are the first features or features derived therefrom;
determining similarities between a feature of a target page and the third features;
selecting whichever tree is, according to the associations, associated with the third feature having the highest similarity to the feature of the target page; and
compressing the target page with the selected tree.

17. The method of claim 9, wherein the memory device comprises a tree cache configured to store the trees for compression,
wherein the memory device, in response to a number of the trees stored in the tree cache exceeding a preset threshold, evicts, from the tree cache, a number of trees exceeding the preset threshold, based on storage periods or usage frequencies of the trees, wherein the trees comprise static Huffman trees (SHTs).

18. An method of operating a compressor for a memory device, the operating method comprising:
receiving a compression request for a target page to be compressed among pages corresponding to application programs;
generating second features of the target page in response to the compression request;
based on similarities of the second features with respect to pre-generated trees for compression, selecting a target tree with the highest similarity with respect to the target page from among the pre-generated trees for compression; and
performing compression on the target page using the selected target tree.

19. The method of claim 18, wherein the generating of the second features comprises:
outputting a compression result for the target page through a Lempel-Ziv (LZ)-based encoder; and
extracting the second features as an array for the compression result for the target page, based on an occurrence frequency ratio for the compression result for the target page.

20. A non-transitory computer-readable storage medium storing instructions that, when executed by a processor, cause the processor to perform the operating method of claim 9.
